(19) United States
(12) Patent Application Publication
(10) Pub. No.: US 2012/0213929 A1
(43) Pub. Date: Aug. 23, 2012

(54) METHOD OF OPERATING FILAMENT ASSISTED CHEMICAL VAPOR DEPOSITION SYSTEM

(75) Inventors: Eric M. LEE, Austin, TX (US); Jacques FAGUET, Albany, NY (US)

(73) Assignee: TOKYO ELECTRON LIMITED, Tokyo (JP)

(21) Appl. No.: 13/030,702

(22) Filed: Feb. 18, 2011

(51) Int. Cl. C23C 16/452

(52) U.S. Cl. 427/255.29; 427/255.28; 427/255.394

(57) ABSTRACT

A method of performing a filament-assisted chemical vapor deposition process is described. The method includes providing a substrate holder in a process chamber of a chemical vapor deposition system, providing a non-ionizing heat source separate from the substrate holder in the process chamber, disposing a substrate on the substrate holder, introducing a film forming composition to the process chamber, thermally fragmenting the film forming composition using the non-ionizing heat source, and forming a thin film on the substrate in the process chamber. The non-ionizing heat source includes a gas heating device through and/or over which the film forming composition flows. The method further includes remotely producing a reactive composition, and introducing the reactive composition to the process chamber to interact with the substrate, wherein the reactive composition is introduced sequentially and/or simultaneously with the introducing the film forming composition.

### CROSS-REFERENCE TO RELATED APPLICATIONS

This application is related to pending U.S. patent application Ser. No. 12/814,278, entitled “APPARATUS FOR CHEMICAL VAPOR DEPOSITION CONTROL”, Docket No. TDC-021, filed on Jun. 11, 2010; pending U.S. patent application Ser. No. 12/814,301, entitled “METHOD FOR CHEMICAL VAPOR DEPOSITION CONTROL”, Docket No. TDC-026, filed on Jun. 11, 2010; pending U.S. patent application Ser. No. 11/693,067, entitled “VAPOR DEPOSITION SYSTEM AND METHOD OF OPERATING”, Docket No. TTCA-195, filed on Mar. 29, 2007; pending U.S. patent application Ser. No. 13/025,133, entitled “VAPOR DEPOSITION SYSTEM”, Docket No. TTCA-195 CIP (Continuation-in-Part of pending U.S. patent application Ser. No. 11/693,067), filed on Feb. 10, 2011; pending U.S. patent application Ser. No. 12/044,574, entitled “GAS HEATING DEVICE FOR A VAPOR DEPOSITION SYSTEM AND METHOD OF OPERATING”, Docket No. TTCA-216, filed on Mar. 7, 2008; and pending U.S. patent application Ser. No. 12/559,398, entitled “HIGH TEMPERATURE GAS HEATING DEVICE FOR A VAPOR DEPOSITION SYSTEM”, Docket No. TTCA-317, filed on Sep. 14, 2009. The entire content of these applications are herein incorporated by reference in their entirety.

### BACKGROUND OF THE INVENTION

1. Field of Invention

The invention relates to a method for treating a substrate, and more particularly to a method for depositing a thin film using a deposition process.

2. Description of Related Art

During material processing, such as semiconductor device manufacturing, vapor deposition is a common technique to form thin films, as well as to form conformal thin films over and within complex topography, on a substrate. Vapor deposition processes can include chemical vapor deposition (CVD) and plasma enhanced CVD (PECVD).

In a CVD process, a continuous stream of film precursor vapor is introduced to a process chamber containing a substrate, wherein the composition of the film precursor has the principal atomic or molecular species found in the film to be formed on the substrate. During this continuous process, the precursor vapor is chemisorbed on the surface of the substrate while it thermally decomposes and reacts with or without the presence of an additional gaseous component that assists the reduction of the chemisorbed material, thus, leaving behind the desired film. However, when using CVD processes, the substrate temperature necessary for thermally decomposing the precursor vapor can be very high, generally in excess of 400 degrees C. which, among other things, adds to the thermal budget for the substrate.

In a PECVD process, the CVD process further includes plasma that is utilized to alter or enhance the film deposition mechanism. For instance, plasma excitation can allow film-forming reactions to proceed at temperatures that are significantly lower than those typically required to produce a similar film by thermally excited CVD. In addition, plasma excitation may activate film-forming chemical reactions that are not energetically or kinetically favored in thermal CVD. However, when using PECVD processes, the substrate temperature may still be high and its contribution to the thermal budget for the substrate may be excessive. Further, the use of plasma can lead to plasma-induced damage, including both physical and/or electrical damage arising from ion bombardment. Moreover, the use of plasma leads to uncontrolled dissociation of the precursor vapor, which, among other things, leads to poor film morphology.

### SUMMARY OF THE INVENTION

The invention relates to a method for treating a substrate, and more particularly to a method for depositing a thin film using a deposition process.

The invention further relates to a method for depositing a thin film using filament assisted chemical vapor deposition (CVD) or pyrolytic CVD, wherein a gas heating device comprising a heating element array is utilized to pyrolize a film forming composition.

According to one embodiment, a method of performing a filament assisted chemical vapor deposition process is described. The method includes providing a substrate holder in a process chamber of a chemical vapor deposition system, providing a non-ionizing heat source separate from the substrate holder in the process chamber, disposing a substrate on the substrate holder, introducing a film forming composition to the process chamber, thermally fragmenting the film forming composition using the non-ionizing heat source, and forming a thin film on the substrate in the process chamber. The non-ionizing heat source includes a gas heating device through and/or over which the film forming composition flows. The method further includes remotely producing a reactive composition, and introducing the reactive composition to the process chamber to interact with the substrate, wherein the reactive composition is introduced sequentially and/or simultaneously with the introducing the film forming composition.

### BRIEF DESCRIPTION OF THE DRAWINGS

In the accompanying drawings:

FIG. 1 illustrates a method of performing a filament assisted chemical vapor deposition process according to another embodiment;

FIG. 2 illustrates a method of depositing a thin film on a substrate according to an embodiment;

FIG. 3 illustrates a method of depositing a thin film on a substrate according to another embodiment;

FIG. 4 is a schematic cross-sectional view of a chemical vapor deposition system according to an embodiment;

FIG. 5 provides a schematic cross-sectional view of a gas distribution system according to an embodiment;

FIG. 6 is a schematic cross-sectional view of a chemical vapor deposition system according to another embodiment;

FIG. 7 provides a schematic cross-sectional view of a gas distribution system according to another embodiment;

FIG. 8A provides a top view of a gas heating device according to an embodiment;

FIG. 8B provides a top view of a heating element according to an embodiment;

FIG. 8C provides a side view of the heating element shown in FIG. 8B;

FIG. 9 provides a top view of a gas heating device according to another embodiment;

FIG. 10 depicts a schematic cross-sectional view of a deposition system according to an embodiment; and

FIG. 11 depicts a schematic cross-sectional view of a deposition system according to another embodiment.

### DETAILED DESCRIPTION OF SEVERAL EMBODIMENTS

In the following description, in order to facilitate a thorough understanding and for purposes of explanation and not limitation, specific details are set forth, such as a method of depositing a thin film on a substrate for a particular application and descriptions of various process conditions used therein.

However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

As described above, the invention relates to a method for treating a substrate, and more particularly to a method for depositing a thin film using a deposition process, such as a vapor deposition process. Moreover, the invention further relates to a method for depositing a thin film using filament assisted chemical vapor deposition (FACVD) or pyrolytic CVD, wherein a gas heating device comprising a heating element array is utilized to pyrolize a film forming composition.

The FACVD process comprises, among other things, process conditions that improve thermal budget (e.g., lower substrate temperature relative to CVD and PECVD processes), reduce plasma-induced damage (e.g., no plasma unlike PECVD), and improve film morphology (e.g., larger molecular fragments via pyrolysis unlike plasma-induced dissociation in PECVD). Additionally, the FACVD process comprises, among other things, process conditions that permit forming thin films on a variety of substrates with adequate adhesion. Furthermore, the FACVD process comprises, among other things, process conditions that possess high precursor utilization.

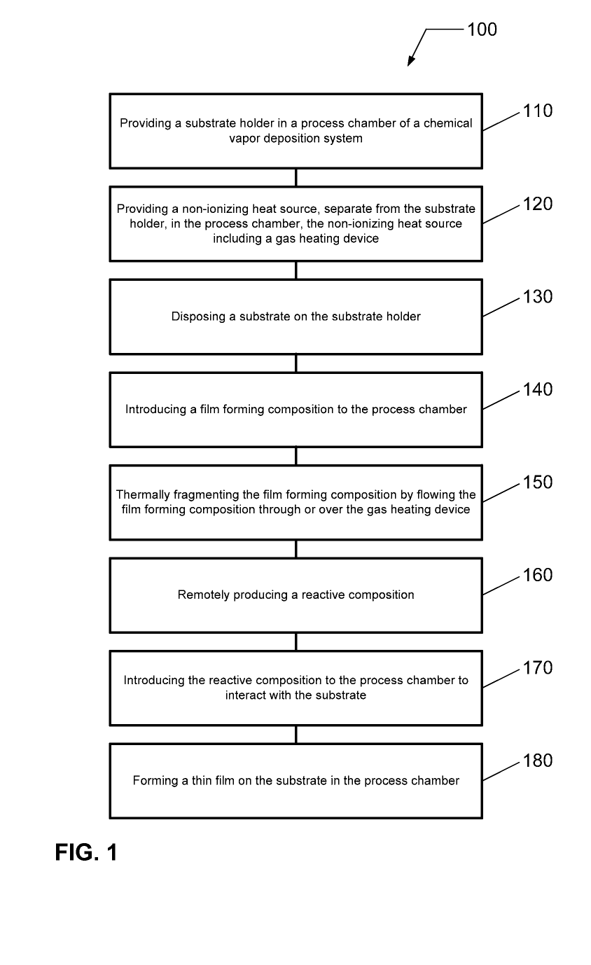

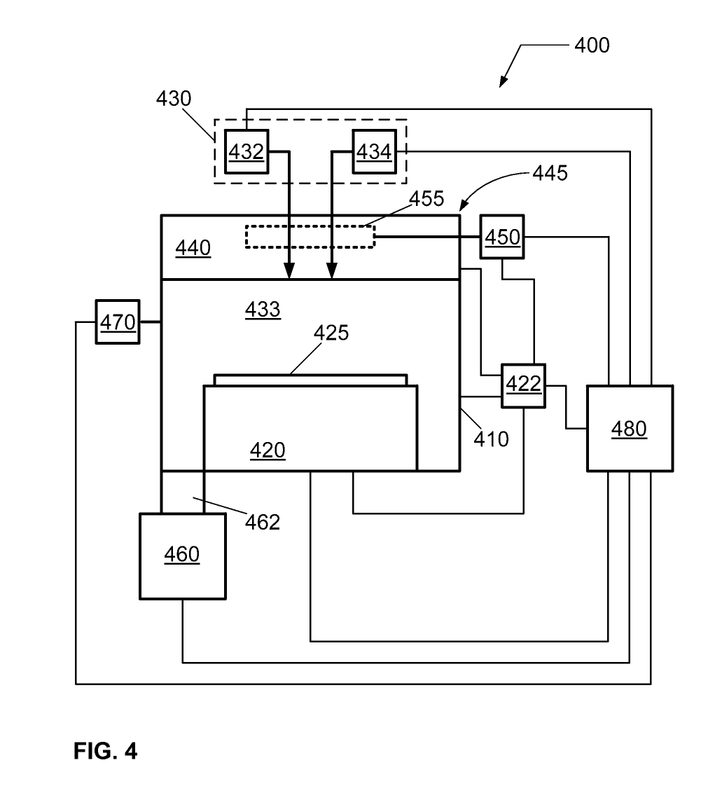

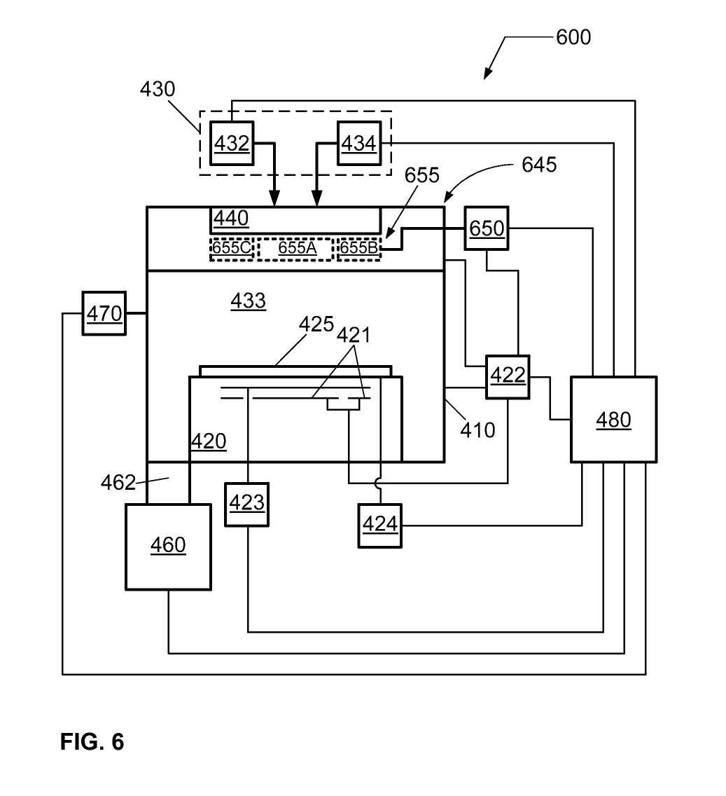

Hence, in accordance with an embodiment of the invention, a method of performing a filament assisted chemical vapor deposition process is illustrated in FIG. 1. The method is represented by a flow chart 100 beginning in 110 with providing a substrate holder in a process chamber of a chemical vapor deposition system. For example, the chemical vapor deposition system can include the chemical vapor deposition system to be described in greater detail below in FIGS. 4 and 6.

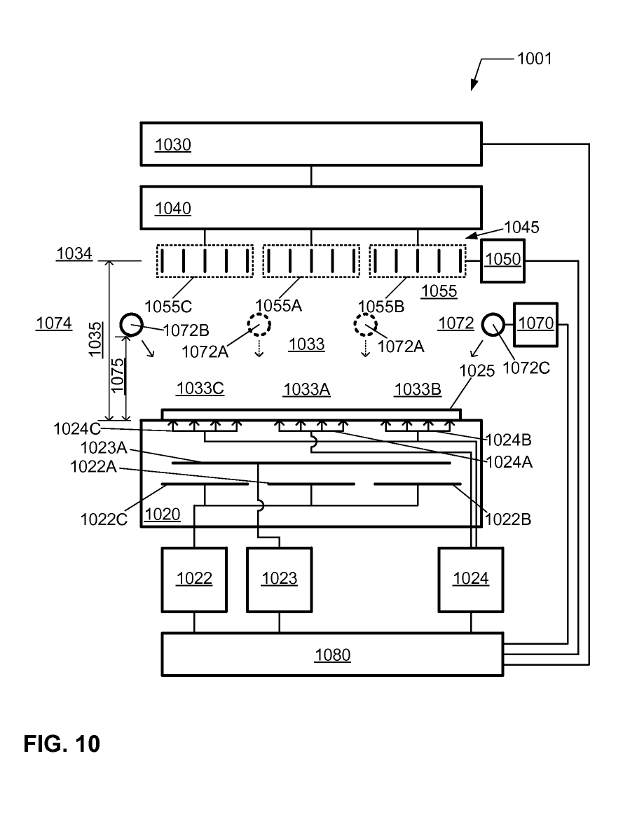

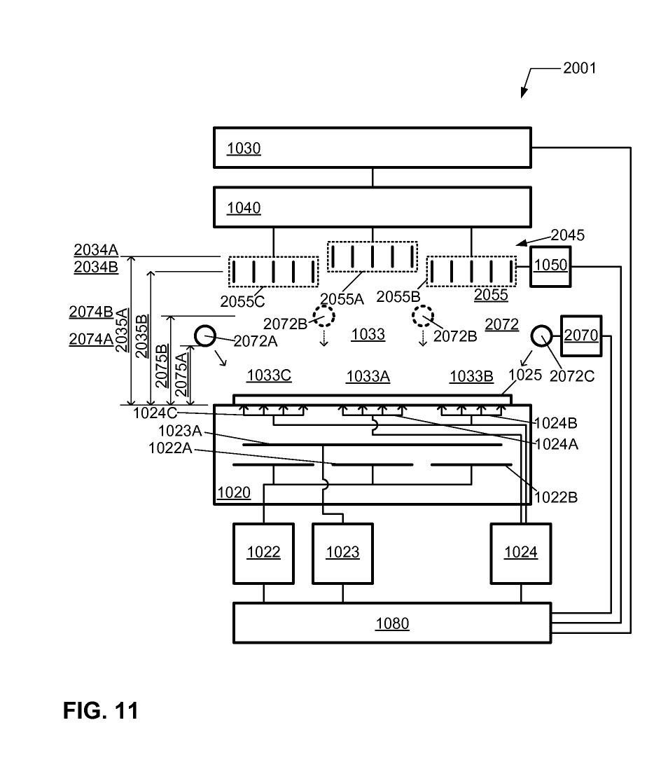

In 120, a non-ionizing heat source, separate from the substrate holder, is provided in the process chamber, wherein the non-ionizing heat source includes a gas heating device. The gas heating device may comprise one or more heating element zones, wherein each heating element zone of the gas heating device comprises one or more resistive heating elements and a mounting structure configured to support the one or more resistive elements. To be described in greater detail below in FIGS. 10 and 11, the method may further comprise spacing each of the one or more heating element zones from the substrate to control a diffusion path length between a reaction zone at each of the one or more heating element zones to a surface of the substrate. For example, the method may comprise differentially spacing each of the one or more heating element zones from the substrate to control a diffusion path length between a reaction zone at each of the plurality of heating element zones to a surface of the substrate. Alternatively or additionally, the method may further comprise differentially orienting each of the one or more heating element zones relative to the substrate to control a diffusion path length between a reaction zone at each of the one or more heating element zones and a surface of the substrate. Further yet, the method may include adjusting the position and/or orientation of at least one of the one or more heating element zones.

In 130, a substrate is disposed on the substrate holder in the process chamber of the chemical vapor deposition system. The substrate may include a variety of substrates including, but not limited to, plastic substrates, non-plastic substrates, silicon-containing substrates, non-silicon-containing substrates, organic substrates, inorganic substrates, conductive substrates, non-conductive substrates, semi-conductive substrates, etc. The substrate may be of any size or shape, for example a 200 mm substrate, a 300 mm substrate, or an even larger substrate. According to an embodiment of the invention, the substrate can be a patterned substrate containing one or more vias or trenches, or combinations thereof. The method may include adjusting a position of the substrate holder relative to the one or more heating element zones.

The substrate holder may comprise one or more temperature control zones for controlling a temperature of the substrate. The one or more temperature control zones may correspond to each of the one or more heating element zones. The one or more temperature control zones may include one or more temperature control elements embedded in the substrate holder for heating and/or cooling different regions of the substrate holder, and/or one or more heat transfer gas supply zones for supplying a heat transfer gas to different regions at a backside of the substrate. As a result, a temperature of the substrate may be independently controlled at the one or more temperature control zones. Further, the temperature of the substrate may be temporally modulated for at least one of the one or more temperature control zones.

In 140, a film forming composition is provided to a gas distribution system that is configured to introduce the film forming composition to the gas heating device coupled to the process chamber of the chemical vapor deposition system above the substrate. For example, the gas distribution system can be located above the substrate and opposing an upper surface of the substrate. The method may further comprise independently controlling a flow rate of the film forming composition to each of the one or more heating element zones. Further yet, the method may comprise temporally modulating or pulsing the flow rate to at least one of the plurality of heating element zones.

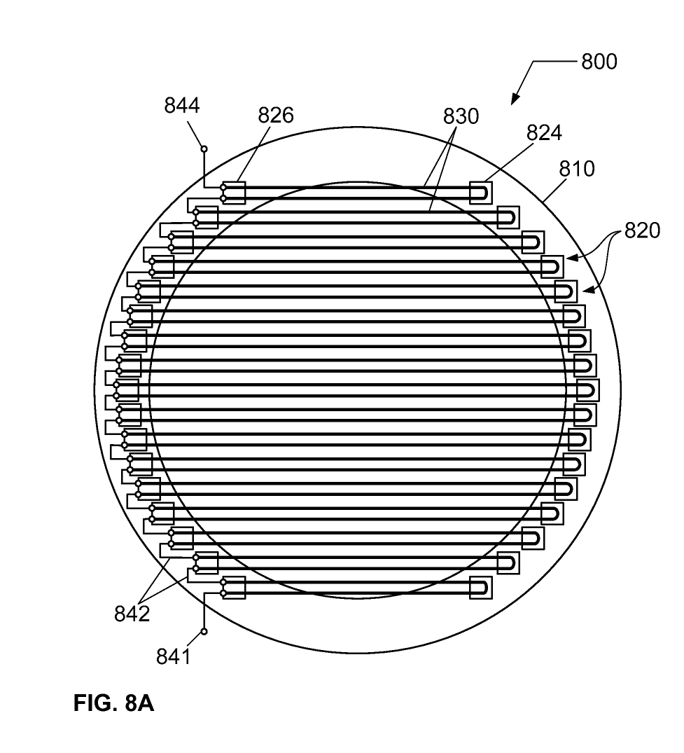

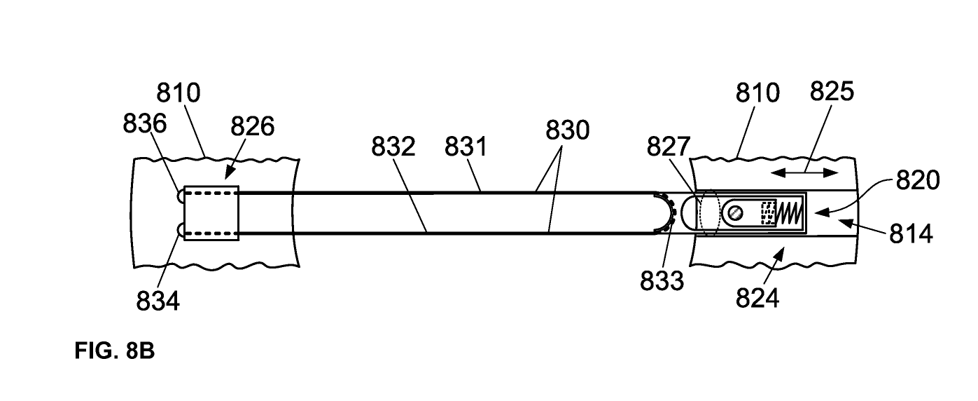

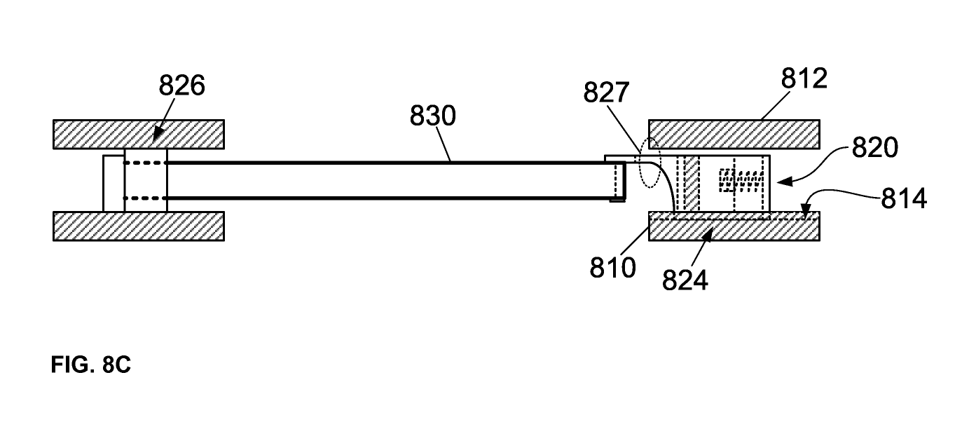

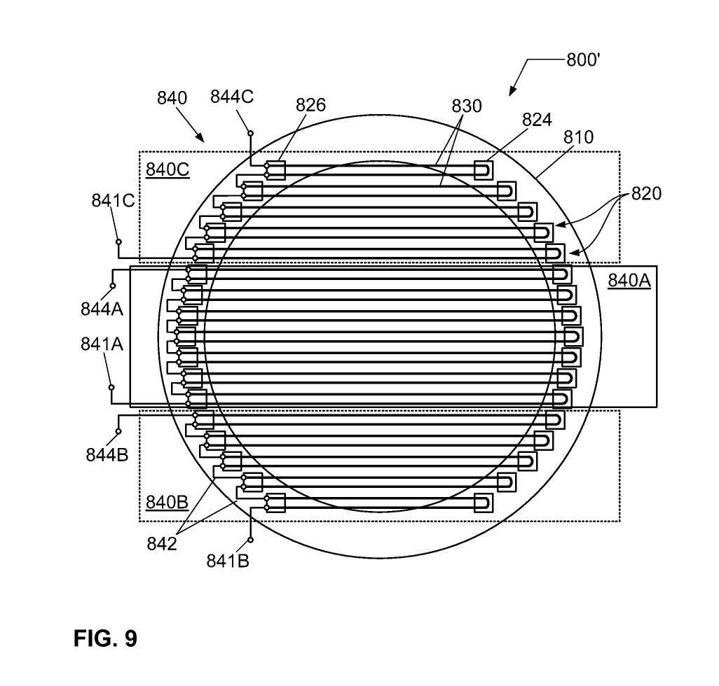

In 150, the film forming composition is thermally fragmented (or subjected to pyrolysis) by flowing the film forming composition through or over the gas heating device. The gas heating device may be any one of the systems described in FIGS. 8A, 8B, 8C, and 9 below, or any combination thereof.

In 160, one or more additives, including a reactive composition, are remotely produced using a remote source. To be described in greater detail below, the remote source may include a remote plasma generator, a remote radical generator, a remote ozone generator, or a remote water vapor generator, or any combination of two or more thereof. For example, the remote source may produce a reactive composition configured to alter the existing surface functionality of a substrate surface, create a new surface functionality at a substrate surface, improve adhesion at a substrate surface for a subsequent layer, hydrolyze a substrate surface, alter the film-forming chemistry at a substrate surface, etc.

The reactive composition may include atomic species, molecular species, excited species, metastable species, dissociated species, radical species, ionized species, etc. The reactive composition may include an oxygen-containing environment (e.g., exposure to oxygen-containing plasma, oxygen-containing radical, atomic oxygen, diatomic oxygen, excited oxygen, metastable oxygen, ionized oxygen, ozone, etc.), a hydrogen-containing environment (e.g., exposure to hydrogen-containing plasma, hydrogen-containing radical, atomic hydrogen, diatomic hydrogen, excited hydrogen, metastable hydrogen, ionized hydrogen, etc.), a nitrogen-containing environment (e.g., exposure to nitrogen-containing plasma, nitrogen-containing radical, atomic nitrogen, diatomic nitrogen, excited nitrogen, metastable nitrogen, ionized nitrogen, etc.), a peroxide, a water vapor environment (e.g., water vapor, hydroxyl radical, hydroxide ion, atomic hydrogen, excited hydrogen, metastable hydrogen, ionized hydrogen, etc.), etc. For example, the remote source may be configured to supply an oxygen-containing additive, such as ionized oxygen, to the chemical vapor deposition system during the introduction of the film forming composition. Alternatively, for example, the remote source may be configured to supply water vapor or a derivative thereof to the chemical vapor deposition system prior to the introduction of the film forming composition.

In 170, the one or more additives are introduced to the process chamber to interact with the substrate. The one or more additives may be introduced from the remote source sequentially and/or simultaneously with the introducing of the film forming composition, i.e., before, during, and/or after the introducing of the film forming composition. To be described in greater detail below in FIGS. 10 and 11, the method may further comprise spacing each of one or more injection zones (for introducing the one or more additives) from the substrate to control a diffusion path length between an injection zone at each of the one or more injection zones to a surface of the substrate. For example, the method may comprise differentially spacing each of the one or more injection zones from the substrate to control a diffusion path length between an injection zone at each of the plurality of injection zones to a surface of the substrate. Further yet, the method may include adjusting the position and/or orientation of at least one of the one or more injection zones.

In 180, the film forming composition is introduced to the substrate in the chemical vapor deposition system, and the substrate is exposed to the film forming composition to facilitate the formation of the thin film. The temperature of the substrate can be set to a value less than the temperature of the one or more heating elements, e.g. one or more resistive film heating elements. For example, the temperature of the substrate can be approximately room temperature. The one or more additives may be used to pre-treat the substrate preceding the forming of the thin film, post-treat the substrate following the forming of the thin film, or assist the film forming reactions on the substrate during the forming of the thin film.

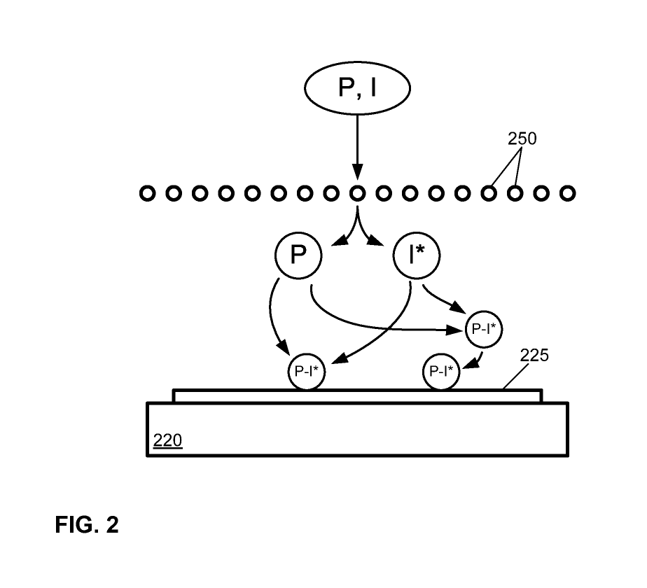

As an example, a FACVD process is illustrated in FIG. 2. Therein, a chemical precursor (P) including a radical initiator (I) flows through, over, or near a heating element 250, such as a resistively-heated conducting filament suspended near or above a surface of a substrate 225 resting on a substrate holder 220. The heating element 250 is elevated to a heat source temperature where the radical initiator (I) decomposes into molecular fragment (I*). The chemical precursor (P) and fragmented radical initiator (I*) can adsorb on the substrate 225 where surface reaction(s) may take place. To cause thermal fragmentation, for instance, the heating element 250 may be elevated to a heat source temperature ranging from about 200 degrees C. to about 700 degrees C. The one or more additives may be used to pre-treat substrate 225 preceding the forming of the thin film, post-treat substrate 225 following the forming of the thin film, or assist the film forming reactions on substrate 225 during the forming of the thin film.

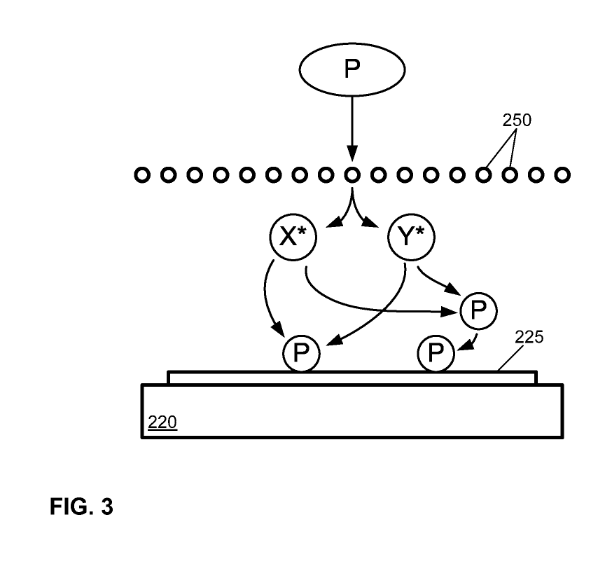

As an alternative example, a FACVD process is illustrated in FIG. 3. Therein, a chemical precursor (P) flows through, over, or near heating element 250. The heating element 250 is elevated to a heat source temperature where the chemical precursor (P) decomposes into molecular fragments (X* and Y*). The molecular fragments can adsorb on the substrate where surface reaction(s) may take place. To cause thermal fragmentation, for instance, the heating element 250 may be elevated to a heat source temperature ranging from about 600 degrees C. to about 1500 degrees C., or from about 600 degrees C. to about 1100 degrees C. The one or more additives may be used to pre-treat substrate 225 preceding the forming of the thin film, post-treat substrate 225 following the forming of the thin film, or assist the film forming reactions on substrate 225 during the forming of the thin film.

Thereafter, the FACVD process of FIGS. 2 and 3 may comprise maintaining the substrate 225 at a substrate temperature sufficiently high to induce deposition and film formation of the gaseous phase molecular fragments on the substrate 225. The substrate holder 220 may be configured to maintain the substrate 225 at a substrate temperature ranging up to 200 degrees C. or greater. Alternatively, the substrate temperature may range up to 100 degrees C. Alternatively yet, the substrate temperature may range up to 80 degrees C. Dependent upon the application, the substrate temperature may have an upper limit. For example, the upper limit for the substrate temperature may be selected to be less than the thermal decomposition temperature of another layer that pre-exists on the substrate 225.

When depositing a Si-containing material using a radical initiator, for example, the substrate holder 220 may be configured to maintain the substrate at a substrate temperature ranging up to about 80 degrees C., and the heating element 250 may be elevated to a heat source temperature ranging from about 200 degrees C. to about 700 degrees C. When depositing a Si-containing material while not using a radical initiator, for example, the substrate holder 320 may be configured to maintain the substrate at a substrate temperature ranging up to about 80 degrees C., and the heating element 350 may be elevated to a heat source temperature ranging from about 600 degrees C. to about 1100 degrees C. When depositing an organic material using a radical initiator, for example, the substrate holder 220 may be configured to maintain the substrate at a substrate temperature ranging up to about 80 degrees C., and the heating element 350 may be elevated to a heat source temperature ranging from about 200 degrees C. to about 700 degrees C.

When preparing a graded organosilicon-containing material, the process gas includes a Si-containing chemical precursor and an organic chemical precursor. During the depositing of the graded organosilicon-containing material, an amount of the Si-containing chemical precursor relative to an amount of the organic chemical precursor is adjusted to spatially vary relative concentrations of Si-containing material and organic material through a thickness of the graded organosilicon-containing material. The adjustment may take place in a step-wise manner, and/or it may take place gradually (e.g., ramp a relative amount up or down).

As described above, the method may comprise disposing a heating element in the chemical vapor deposition system, wherein the process gas, including the chemical precursor with or without the radical initiator, flows through, over, or by the heating element 250. For example, the temperature of the heating element 250 is elevated such that when the chemical precursor flows through, over, or by the heating element 250, the chemical precursor may decompose into two or more molecular fragments. The fragments of the chemical precursor can adsorb on the substrate 225 where surface reaction may take place.

The heating element may comprise a filament composed of a tungsten-containing material, a tantalum-containing material, a molybdenum-containing material, a rhenium-containing material, a rhodium-containing material, a platinum-containing material, a chromium-containing material, an iridium-containing material, a carbon-containing material, or a nickel-containing material, or a combination thereof. The temperature range for the heating element depends on the material properties of the heating element. For example, the temperature of the heating element may range from about 200 degrees C. to about 1500 degrees C. Additionally, for example, the temperature of the heating element may range from about 200 degrees C. to about 1100 degrees C.

Before, during, or after the deposition of the thin film, the substrate or preceding layer may be treated using one or more additives to alter the existing surface functionality of a substrate surface, create a new surface functionality at a substrate surface, improve adhesion at a substrate surface for a subsequent layer, hydrolyze a substrate surface, alter the film-forming chemistry at a substrate surface, etc.

The substrate or the preceding layer may be chemically treated with or without a FACVD process, thermally treated, treated with an oxygen-containing environment (e.g., exposure to oxygen-containing plasma, oxygen-containing radical, atomic oxygen, diatomic oxygen, excited oxygen, metastable oxygen, ionized oxygen, ozone, etc.), treated with a hydrogen-containing environment (e.g., exposure to hydrogen-containing plasma, hydrogen-containing radical, atomic hydrogen, diatomic hydrogen, excited hydrogen, metastable hydrogen, ionized hydrogen, etc.), treated with a nitrogen-containing environment (e.g., exposure to nitrogen-containing plasma, nitrogen-containing radical, atomic nitrogen, diatomic nitrogen, excited nitrogen, metastable nitrogen, ionized nitrogen, etc.), treated with a peroxide, exposed to an energy source, treated with a water vapor environment (e.g., water vapor, hydroxyl radical, hydroxide ion, atomic hydrogen, excited hydrogen, metastable hydrogen, ionized hydrogen, etc.), etc.

The energy source may comprise a coherent source of electro-magnetic radiation, such as a laser, or a non-coherent source of electro-magnetic radiation, such as a lamp, or both. Additionally, the energy source may comprise a photon source, an electron source, a plasma source, a microwave radiation source, an ultraviolet (UV) radiation source, an infrared (IR) radiation source, a visible radiation source, or a thermal energy source, or any combination of two or more thereof.

During and/or following the deposition of the thin film, the thin film may be treated. The thin film may be cured to, for example, improve the mechanical properties (e.g., Young's modulus, hardness, etc.). For example, the treatment may be performed in-situ (within the same process chamber for the deposition process) during and/or after the deposition process. Additionally, for example, the treatment may be performed ex-situ (outside of the process chamber for the deposition process) after the deposition process.

During and/or following the deposition of the thin film, the thin film may be exposed to an energy source. The energy source may comprise a coherent source of electro-magnetic radiation, such as a laser, or a non-coherent source of electro-magnetic radiation, such as a lamp, or both. Additionally, the energy source may comprise a photon source, an electron source, a plasma source, a microwave radiation source, an ultraviolet (UV) radiation source, an infrared (IR) radiation source, a visible radiation source, or a thermal energy source, or any combination of two or more thereof.

According to an embodiment, FIG. 4 schematically illustrates a chemical vapor deposition system 400 for depositing a thin film including, for example, a Si-containing material, or an organic material, or a graded organosilicon-containing material. Chemical vapor deposition system 400 can facilitate a chemical vapor deposition (CVD) process, whereby a film forming composition that includes a chemical precursor to the formation of the thin film, such as a Si-containing chemical precursor or an organic chemical precursor or both, is thermally activated or decomposed in order to form the thin film on a substrate.

The chemical vapor deposition system 400 comprises a process chamber 410 having a substrate holder 420 configured to support a substrate 425, upon which the thin film is deposited or formed. Furthermore, the substrate holder 420 is configured to control the temperature of the substrate 425 at a temperature suitable for the film forming reactions.

The process chamber 410 is coupled to a film forming composition delivery system 430 configured to introduce a film forming composition or process gas to the process chamber 410 through a gas distribution system 440. Furthermore, a gas heating device 445 is coupled to the gas distribution system 440 and configured to chemically modify the film forming composition or process gas. The gas heating device 445 comprises one or more heating elements 455 configured to interact with one or more constituents in the process gas, and a power source 450 that is coupled to the one or more heating elements 455 and is configured to deliver power to the one or more heating elements 455. For example, the one or more heating elements 455 can comprise one or more resistive heating elements. When electrical current flows through and affects heating of the one or more resistive heating elements, the interaction of these heated elements with one or more constituents in the process gas causes thermal fragmentation or pyrolysis of one or more constituents of the process gas.

The process chamber 410 is further coupled to a vacuum pumping system 460 through a duct 462, wherein the vacuum pumping system 460 is configured to evacuate the process chamber 410 and the gas distribution system 440 to a pressure suitable for forming the thin film on the substrate 425 and suitable for pyrolysis of the process gas. The pressure in process chamber 410 may range up to about 500 Torr. Alternatively, the pressure in process chamber 410 may range up to about 100 Torr. Alternatively yet, the pressure in process chamber 410 may range from about 0.1 Torr to about 40 Torr.

The film forming composition delivery system 430 can include one or more material sources configured to introduce the process gas to the gas distribution system 440. For example, the process gas may include one or more gases, or one or more vapors formed in one or more gases, or a mixture of two or more thereof. The film forming composition delivery system 430 can include one or more gas sources, or one or more vaporization sources, or a combination thereof. Herein vaporization refers to the transformation of a material (normally stored in a state other than a gaseous state) from a non-gaseous state to a gaseous state. Therefore, the terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas, or liquid to gas.

When the process gas is introduced to the gas distribution system 440, one or more constituents of the process gas are subjected to pyrolysis by the gas heating device 445 described above. The process gas can include a chemical precursor or precursors that may be fragmented by pyrolysis in the gas distribution system 440. The chemical precursor or precursors may include the principal atomic or molecular species of the film desired to be produced on the substrate. For example, the chemical precursor or precursors may include each atomic element desired for the film to be deposited.

According to one embodiment, the film forming composition delivery system 430 can include a first material source 432 configured to introduce a chemical precursor, to the gas distribution system 440, and a second material source 434 configured to introduce an oxidizing agent, a radical initiator, an inert gas, a carrier gas, a dilution gas, or an additive as described above. For example, the inert gas, carrier gas or dilution gas can include a noble gas, i.e., He, Ne, Ar, Kr, Xe, or Rn.

The one or more heating elements 455 can comprise one or more resistive heating elements. Additionally, for example, the one or more heating elements 455 may include a metal-containing ribbon or filament. Furthermore, for example, the one or more heating elements 455 can be composed of a resistive metal, a resistive metal alloy, a resistive metal nitride, or a combination of two or more thereof. The one or more heating elements 455 may comprise a filament or ribbon composed of a tungsten-containing material, a tantalum-containing material, a molybdenum-containing material, a rhenium-containing material, a rhodium-containing material, a platinum-containing material, a chromium-containing material, an iridium-containing material, a carbon-containing material, or a nickel-containing material, or a combination thereof.

When the power source 450 couples electrical power to the one or more heating elements 455, the one or more heating elements 455 may be elevated to a temperature sufficient to pyrolize one or more constituents of the process gas. Power source 450 may include a direct current (DC) power source, or it may include an alternating current (AC) power source. Power source 450 may be configured to couple electrical power to the one or more heating elements 455 through a direct electrical connection to the one or more heating elements 455. Alternatively, power source 450 may be configured to couple electrical power to the one or more heating elements 455 through induction. Furthermore, for example, the power source 450 can be configured to modulate the amplitude of the power, or pulse the power. Furthermore, for example, the power source 450 can be configured to perform at least one of setting, monitoring, adjusting or controlling a power, a voltage, or a current.

Referring still to FIG. 4, a temperature control system 422 can be coupled to the gas distribution system 440, the gas heating device 445, the process chamber 410 and/or the substrate holder 420, and configured to control the temperature of one or more of these components. The temperature control system 422 can include a temperature measurement system configured to measure the temperature of the gas distribution system 440 at one or more locations, the temperature of the gas heating device 445 at one or more locations, the temperature of the process chamber 410 at one or more locations and/or the temperature of the substrate holder 420 at one or more locations. The measurements of temperature can be used to adjust or control the temperature at one or more locations in chemical vapor deposition system 400.

The temperature measuring device, utilized by the temperature measurement system, can include an optical fiber thermometer, an optical pyrometer, a band-edge temperature measurement system as described in pending U.S. Pat. No. 6,891,124, or a thermocouple such as a K-type thermocouple. Examples of optical thermometers include: an optical fiber thermometer commercially available from Advanced Energies, Inc., Model No. OR2000F; an optical fiber thermometer commercially available from Luxtron Corporation, Model No. M600; or an optical fiber thermometer commercially available from Takaoka Electric Mfg., Model No. FT-1420.

Alternatively, when measuring the temperature of one or more resistive heating elements, the electrical characteristics of each resistive heating element can be measured. For example, two or more of the voltage, current or power coupled to the one or more resistive heating elements can be monitored in order to measure the resistance of each resistive heating element. The variations of the element resistance can arise due to variations in temperature of the element which affects the element resistivity.

According to program instructions from the temperature control system 422 or controller 480 or both, the power source 450 can be configured to operate the gas heating device 445, e.g., the one or more heating elements, at a temperature ranging up to approximately 1500 degrees C. For example, the temperature can range from approximately 500 degrees C. to approximately 1500 degrees C. Additionally, for example, the temperature can range from approximately 500 degrees C. to approximately 1300 degrees C. The temperature can be selected based upon the process gas and, more particularly, the temperature can be selected based upon a constituent of the process gas, such as the chemical precursor(s).

Additionally, according to program instructions from the temperature control system 422 or the controller 480 or both, the temperature of the gas distribution system 440 can be set to a value less than the temperature of the gas heating device 445, i.e., the one or more heating elements. The temperature can be selected to be less than the temperature of the one or more heating elements, and to be sufficiently high to prevent condensation which may or may not cause film formation on surfaces of the gas distribution system and reduce the accumulation of residue.

Additionally yet, according to program instructions from the temperature control system 422 or the controller 480 or both, the temperature of the process chamber 410 can be set to a value less than the temperature of the gas heating device 445, i.e., the one or more heating elements. The temperature can be selected to be less than the temperature of the one or more resistive film heating elements, and to be sufficiently high to prevent condensation which may or may not cause film formation on surfaces of the process chamber and reduce the accumulation of residue.

Once the process gas enters the process space 433, constituents of the process gas adsorbs on the substrate surface, and film forming reactions proceed to produce a thin film on the substrate 425. According to program instructions from the temperature control system 422 or the controller 480 or both, the substrate holder 420 is configured to set the temperature of substrate 425 to a value less than the temperature of the gas heating device 445.

As an example, the substrate temperature can range up to about 80 degrees C. The substrate holder 420 comprises one or more temperature control elements coupled to the temperature control system 422. The temperature control system 422 can include a substrate heating system, or a substrate cooling system, or both. For example, substrate holder 420 can include a substrate heating element or substrate cooling element (not shown) beneath the surface of the substrate holder 420. For instance, the heating system or cooling system can include a re-circulating fluid flow that receives heat from substrate holder 420 and transfers heat to a heat exchanger system (not shown) when cooling, or transfers heat from the heat exchanger system to the substrate holder 420 when heating. The cooling system or heating system may include heating/cooling elements, such as resistive heating elements, or thermo-electric heaters/coolers located within substrate holder 420. Additionally, the heating elements or cooling elements or both can be arranged in more than one separately controlled temperature zone. The substrate holder 420 may have two thermal zones, including an inner zone and an outer zone. The temperatures of the zones may be controlled by heating or cooling the substrate holder thermal zones separately.

Additionally, the substrate holder 420 comprises a substrate clamping system (e.g., electrical or mechanical clamping system) to clamp the substrate 425 to the upper surface of substrate holder 420. For example, substrate holder 420 may include an electrostatic chuck (ESC).

Furthermore, the substrate holder 420 can facilitate the delivery of heat transfer gas to the back-side of substrate 425 via a backside gas supply system to improve the gas-gap thermal conductance between substrate 425 and substrate holder 420. Such a system can be utilized when temperature control of the substrate is required at elevated or reduced temperatures. For example, the backside gas system can comprise a two-zone gas distribution system, wherein the backside gas (e.g., helium) pressure can be independently varied between the center and the edge of substrate 425.

Vacuum pumping system 460 can include a turbo-molecular vacuum pump (TMP) capable of a pumping speed up to approximately 5000 liters per second (and greater) and a gate valve for throttling the chamber pressure. For example, a 1000 to 3000 liter per second TMP can be employed. TMPs can be used for low pressure processing, typically less than approximately 1 Torr. For high pressure processing (i.e., greater than approximately 1 Torr), a mechanical booster pump and/or a dry roughing pump can be used. Furthermore, a device for monitoring chamber pressure (not shown) can be coupled to the process chamber 410. The pressure measuring device can be, for example, a capacitance manometer.

The chemical vapor deposition system 400 may further include a remote source 470 for introducing one or more additives before, during, and/or after the introducing of the film forming composition. The one or more additives may be used to pre-treat a surface on the substrate 425, post-treat a surface on the substrate 425, or assist the film forming reactions on a surface of the substrate 425. The remote source 470 may include a remote plasma generator, a remote radical generator, a remote ozone generator, or a remote water vapor generator, or any combination of two or more thereof. For example, the remote source 470 may produce a reactive composition configured to alter the existing surface functionality of a substrate surface, create a new surface functionality at a substrate surface, improve adhesion at a substrate surface for a subsequent layer, hydrolyze a substrate surface, alter the film-forming chemistry at a substrate surface, etc.

The reactive composition may include atomic species, molecular species, excited species, metastable species, dissociated species, radical species, ionized species, etc. The reactive composition may include an oxygen-containing environment (e.g., exposure to oxygen-containing plasma, oxygen-containing radical, atomic oxygen, diatomic oxygen, excited oxygen, metastable oxygen, ionized oxygen, ozone, etc.), a hydrogen-containing environment (e.g., exposure to hydrogen-containing plasma, hydrogen-containing radical, atomic hydrogen, diatomic hydrogen, excited hydrogen, metastable hydrogen, ionized hydrogen, etc.), a nitrogen-containing environment (e.g., exposure to nitrogen-containing plasma, nitrogen-containing radical, atomic nitrogen, diatomic nitrogen, excited nitrogen, metastable nitrogen, ionized nitrogen, etc.), a peroxide, a water vapor environment (e.g., water vapor, hydroxyl radical, hydroxide ion, atomic hydrogen, excited hydrogen, metastable hydrogen, ionized hydrogen, etc.), etc. For example, the remote source 470 may be configured to supply an oxygen-containing additive, such as ionized oxygen, to the chemical vapor deposition system 400 during the introduction of the film forming composition.

As an example, the remote plasma generator may include an upstream plasma source configured to generate the reactive composition. The remote plasma generator may include an ASTRON® reactive gas generator, commercially available from MKS Instruments, Inc., ASTeX® Products (90 Industrial Way, Wilmington, Mass. 01887).

Additionally, the chemical vapor deposition system 400 can be periodically cleaned using an in-situ cleaning system (not shown) coupled to, for example, the process chamber 410 or the gas distribution system 440. The remote source 470 may be utilized to provide a cleaning composition to the chemical vapor deposition system 400. Per a frequency determined by the operator, the in-situ cleaning system can perform routine cleanings of the chemical vapor deposition system 400 in order to remove accumulated residue on internal surfaces of chemical vapor deposition system 400. The in-situ cleaning system can, for example, comprise a radical generator configured to introduce chemical radical capable of chemically reacting and removing such residue. Additionally, for example, the in-situ cleaning system can, for example, include an ozone generator configured to introduce a partial pressure of ozone. For instance, the radical generator can include an upstream plasma source configured to generate oxygen or fluorine radical from oxygen (O₂), nitrogen trifluoride (NF), O₃, XeF₂, ClF₃, or C₃F₈ (or, more generally, CₓF_{y}), respectively. The radical generator can include an ASTRON® reactive gas generator, commercially available from MKS Instruments, Inc., ASTeX® Products (90 Industrial Way, Wilmington, Mass. 01887).

Referring still to FIG. 4, the chemical vapor deposition system 400 can further comprise controller 480 that comprises a microprocessor, memory, and a digital I/O port capable of generating control voltages sufficient to communicate and activate inputs to chemical vapor deposition system 400 as well as monitor outputs from chemical vapor deposition system 400. Moreover, controller 480 can be coupled to and can exchange information with the process chamber 410, the substrate holder 420, the temperature control system 422, the film forming composition delivery system 430, the gas distribution system 440, the gas heating device 445, the vacuum pumping system 460, and the remote source 470, as well as the backside gas delivery system (not shown), and/or the electrostatic clamping system (not shown). A program stored in the memory can be utilized to activate the inputs to the aforementioned components of chemical vapor deposition system 400 according to a process recipe in order to perform the method of depositing a thin film.

Controller 480 may be locally located relative to the chemical vapor deposition system 400, or it may be remotely located relative to the chemical vapor deposition system 400 via an internet or intranet. Thus, controller 480 can exchange data with the chemical vapor deposition system 400 using at least one of a direct connection, an intranet, or the internet. Controller 480 may be coupled to an intranet at a customer site (i.e., a device maker, etc.), or coupled to an intranet at a vendor site (i.e., an equipment manufacturer). Furthermore, another computer (i.e., controller, server, etc.) can access controller 480 to exchange data via at least one of a direct connection, an intranet, or the internet.

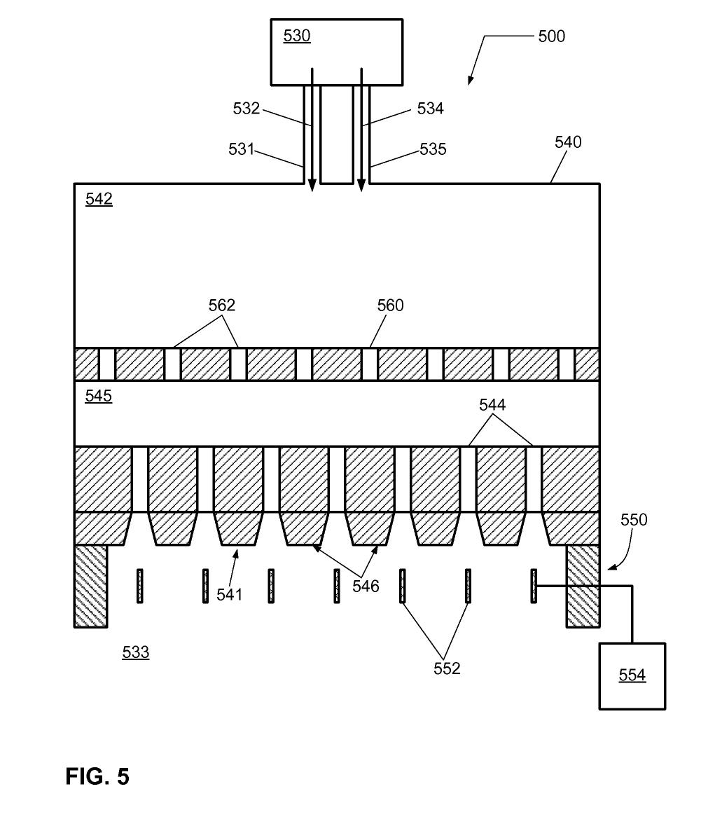

Referring now to FIG. 5, a gas distribution system 500 is illustrated according to an embodiment. The gas distribution system 500 comprises a housing 540 configured to be coupled to or within a process chamber of a deposition system (such as process chamber 410 of chemical vapor deposition system 400 in FIG. 4), and a gas distribution plate 541 configured to be coupled to the housing 540, wherein the combination form a plenum 542. The gas distribution system 500 may be thermally insulated from the process chamber, or it may not be thermally insulated from the process chamber.

The gas distribution system 500 is configured to receive and provide a film forming composition or process gas into the plenum 542 from a film forming composition delivery system 530 and distribute the film forming composition in the process chamber. For example, the gas distribution system 500 can be coupled to the film forming composition delivery system 530 using a first supply line 531 configured to provide one or more constituents of a film forming composition 532, such as a chemical precursor, and a second supply line 535 configured to provide an optional inert gas 534 into plenum 542 from the film forming composition delivery system 530. The one or more constituents of the film forming composition 532 and the optional inert gas 534 may be introduced to plenum 542 separately as shown, or they may be introduced through the same supply line.

The gas distribution plate 541 comprises a plurality of openings 544 arranged to introduce and distribute the film forming composition from plenum 542 to a process space 533 proximate a substrate (not shown) upon which a film is to be formed. For example, gas distribution plate 541 comprises an outlet 546 configured to face the upper surface of a substrate. Furthermore, for example, the gas distribution plate 541 may include gas showerhead.

Furthermore, the gas distribution system 500 comprises a gas heating device 550 having one or more heating elements 552 coupled to a power source 554 and configured to receive an electrical current from the power source 554. The one or more heating elements 552 are located at the outlet 546 of the gas distribution system 500, such that they may interact with any constituent of the film forming composition, or all of the constituents of the film forming composition.

For example, the one or more heating elements 552 can comprise one or more resistive heating elements. Additionally, for example, the one or more heating elements 552 may include a metal-containing ribbon or a metal-containing wire. Furthermore, for example, the one or more heating elements 552 can be composed of a resistive metal, a resistive metal alloy, a resistive metal nitride, a carbon-containing material, or a combination of two or more thereof.

When the power source 554 couples electrical power to the one or more heating elements 552, the one or more heating elements 552 may be elevated to a temperature sufficient to pyrolize one or more constituents of the film forming composition. Power source 554 may include a direct current (DC) power source, or it may include an alternating current (AC) power source. Power source 554 may be configured to couple electrical power to the one or more heating elements 552 through a direct electrical connection to the one or more heating elements 552. Alternatively, power source 554 may be configured to couple electrical power to the one or more heating elements 552 through induction.

The one or more openings 544 formed in gas distribution plate 541 can include one or more orifices, one or more nozzles, or one or more slots, or a combination thereof. The one or more openings 544 can include a plurality of orifices distributed on the gas distribution plate 541 in a rectilinear pattern. Alternatively, the one or more openings 544 can include a plurality of orifices distributed on the gas distribution plate 541 in a circular pattern (e.g., orifices are distributed in a radial direction or angular direction or both). When the one or more heating elements 552 are located at the outlet 546 of the gas distribution system 500, each heating element can be positioned such that the flow of film forming composition exiting from the one or more openings 544 of gas distribution plate 541 pass by or over each heating element.

Additionally, the plurality of openings 544 can be distributed in various density patterns on the gas distribution plate 541. For example, more openings can be formed near the center of the gas distribution plate 541 and less openings can be formed near the periphery of the gas distribution plate 541. Alternatively, for example, more openings can be formed near the periphery of the gas distribution plate 541 and less openings can be formed near the center of the gas distribution plate 541. Additionally yet, the size of the openings can vary on the gas distribution plate 541. For example, larger openings can be formed near the center of the gas distribution plate 541 and smaller openings can be formed near the periphery of the gas distribution plate 541. Alternatively, for example, smaller openings can be formed near the periphery of the gas distribution plate 541 and larger openings can be formed near the center of the gas distribution plate 541.

Referring still to FIG. 5, the gas distribution system 500 may comprise an optional intermediate gas distribution plate 560 coupled to housing 540 such that the combination of housing 540, intermediate gas distribution plate 560 and gas distribution plate 541 form an intermediate plenum 545 separate from plenum 542 and between the intermediate gas distribution plate 560 and the gas distribution plate 541. The gas distribution system 500 is configured to receive a film forming composition into the plenum 542 from a film forming composition delivery system (not shown) and distribute the film forming composition through the intermediate plenum 545 to the process chamber.

The intermediate gas distribution plate 560 comprises a plurality of openings 562 arranged to distribute and introduce the film forming composition to the intermediate plenum 545. The plurality of openings 562 can be shaped, arranged, distributed or sized as described above.

In alternative embodiments, the gas distribution system may include a gas ring, a gas nozzle, an array of gas nozzles, or combinations thereof.

According to another embodiment, FIG. 6 schematically illustrates a chemical vapor deposition system 600 for depositing a thin film including, for example, a Si-containing material, or an organic material, or a graded organosilicon-containing material. The chemical vapor deposition system 600 can be similar to the embodiment of FIG. 4, and can further comprise a gas heating device 645 that comprises a heating element array 655 having a plurality of heating element zones 655 (A,B,C). The plurality of heating element zones 655 (A,B,C) are configured to receive a flow of a film forming composition from the film forming composition delivery system 430 and the gas distribution system 440 across or through the plurality of heating element zones 655 (A,B,C) in order to cause pyrolysis of one or more constituents of the film forming composition when heated. Each of the plurality of heating element zones 655 (A,B,C) comprises one or more heating elements, and is configured electrically independent of one another, wherein each of the plurality of heating element zones 655 (A,B,C) is arranged to interact with at least a portion of the flow, and affect pyrolysis of and delivery of the film forming composition to different process regions of the substrate 425. Although three heating element zones and process regions are illustrated, the heating element array 655 may be configured with less (e.g., two) or more (e.g., four, five, etc.).

As indicated above, the plurality of heating element zones 655 (A,B,C) may facilitate the modification and/or spatial/temporal control of the reaction zone at the heating element array, e.g., spatial and/or temporal adjustment of the film forming chemistry at the reaction zone; and/or the modification and/or spatial/temporal control of the diffusion path length between the reaction zone (i.e., the heating element array) and the substrate or substrate holder. For example, the spacing and/or orientation of the plurality of heating element zones 655 (A,B,C) relative to one another and/or the substrate may be adjusted.

One or more power sources 650 are coupled to the heating element array 655, and configured to provide an electrical signal to each of the plurality of heating element zones 655 (A,B,C). For example, each of the heating element zones 655 (A,B,C) may comprise one or more resistive heating elements. When electrical current flows through and affects heating of the one or more resistive heating elements, the interaction of these heated elements with the film forming composition causes pyrolysis of one or more constituents of the film forming composition.

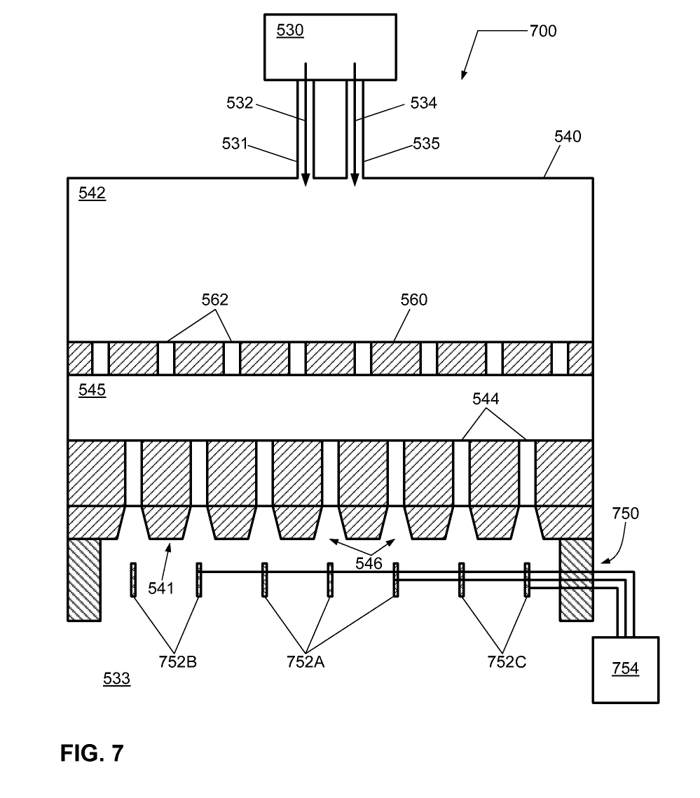

Referring now to FIG. 7, a gas distribution system 700 is illustrated according to another embodiment. The gas distribution system 700 can be similar to the embodiment of FIG. 5, and can further comprise a gas heating device 750 having a heating element array with a plurality of heating element zones 752 (A-C). Each of the plurality of heating element zones 752 (A-C) includes one or more heating elements coupled to a power source 754, and configured to receive an electrical signal from the power source 754. The plurality of heating element zones 752 (A-C) are located at the outlet 546 of the gas distribution system 700, such that they may interact with any constituent of the film forming composition, or all of the constituents of the film forming composition including an optional radical initiator.

As described above, each of the plurality of heating element zones 752 (A-C) can comprise one or more resistive heating elements. For example, the one or more resistive heating elements may include a metal-containing ribbon or a metal-containing wire. Furthermore, for example, the one or more resistive heating elements can be composed of a resistive metal, a resistive metal alloy, a resistive metal nitride, a carbon-containing material, or a combination of two or more thereof.

When the power source 754 couples electrical power to the plurality of heating element zones 752 (A-C), the plurality of heating element zones 752 (A-C) may be elevated to a temperature sufficient to pyrolize one or more constituents of the film forming composition. Power source 754 may include a direct current (DC) power source, or it may include an alternating current (AC) power source. Power source 754 may be configured to couple electrical power to the plurality of heating element zones 752 (A-C) through a direct electrical connection to the one or more heating elements. Alternatively, power source 754 may be configured to couple electrical power to the plurality of heating element zones 752 (A-C) through induction.

The one or more openings 544 formed in gas distribution plate 541 can include one or more orifices or one or more slots or a combination thereof. The one or more openings 544 can be distributed on the gas distribution plate 541 in a rectilinear pattern. Alternatively, the one or more openings 544 can be distributed on the gas distribution plate 541 in a circular pattern (e.g., orifices are distributed in a radial direction or angular direction or both). When the plurality of heating element zones 752 (A-C) are located at the outlet 546 of the gas distribution system 700, each heating element can be positioned such that the flow of film forming composition and/or the optional initiator exiting from the one or more openings 544 of gas distribution plate 541 pass by or over at least one heating element.

Referring now to FIG. 8A, a top view of a gas heating device 800 is presented according to an embodiment. The gas heating device 800 is configured to heat one or more constituents of a film forming composition. The gas heating device 800 comprises one or more heat sources 820, wherein each heat source 820 comprises a resistive heating element 830 configured to receive an electrical current from one or more power sources. Additionally, the gas heating device 800 comprises a mounting structure 810 configured to support the one or more resistive heating elements 830. Furthermore, the one or more heat sources 820 may be mounted between the mounting structure 810 and an auxiliary mounting structure 812 (see FIGS. 8C).

As shown in FIG. 8A, the gas heating device 800 comprises one or more static mounting devices 826 coupled to the mounting structure 810 and configured to fixedly couple the one or more resistive heating elements 830 to the mounting structure 810, and the gas heating device 800 comprises one or more dynamic mounting devices 824 coupled to the mounting structure 810 and configured to automatically compensate for changes in a length of each of the one or more resistive heating elements 830. Further yet, the one or more dynamic mounting devices 824 may substantially reduce slippage between the one or more resistive heating elements 830 and the one or more dynamic mounting devices 824.

The one or more resistive heating elements 830 may be electrically coupled in series, as shown in FIG. 8A, using electrical interconnects 842, wherein electrical current is supplied to the serial connection of one or more resistive heating elements 830 via, for example, connection of a first terminal 840 to the power source and a second terminal 844 to electrical ground for the power source. Alternatively, the one or more resistive heating elements 830 may be electrically coupled in parallel.

Referring now to FIGS. 8B and 8C, a top view and a side view of heat source 820, respectively, is presented according to an embodiment. The resistive heating element 830 comprises a first end 834 fixedly coupled to one of the one or more static mounting devices 826, a second end 836 fixedly coupled to one of the one or more static mounting devices 826, a bend 833 coupled to one of the one or more dynamic mounting devices 824 and located between the first end 834 and the second end 836, a first straight section 832 extending between the first end 834 and the bend 833, and a second straight section 831 extending between the second end 836 and the bend 833. The first end 834 and the second end 836 may be fixedly coupled to the same static mounting device or different static mounting devices.

As illustrated in FIGS. 8B and 8C, the first straight section 832 and the second straight section 831 may be substantially the same length. When the first straight section 832 and the second straight section 831 are substantially the same length, the respective changes in length for the first straight section 832 and the second straight section 831 due to temperature variations are substantially the same. Alternatively, the first straight section 832 and the second straight section 831 may be different lengths.

Also, as illustrated in FIGS. 8B and 8C, the bend 833 comprises a 180 degree bend. Alternatively, the bend 833 comprises a bend ranging from greater than 0 degrees to less than 360 degrees.

The static mounting device 826 is fixedly coupled to the mounting structure 810. The dynamic mounting device 824 is configured to adjust in a linear direction 825 parallel with the first straight section 832 and the second straight section 831 in order to compensate for changes in the length of the first straight section 832 and the length of the second straight section 831. In this embodiment, the dynamic mounting device 824 can alleviate slack or sagging in the resistive heating element 830, and it may substantially reduce or minimize slippage between the resistive heating element 830 and the dynamic mounting device 824 (such slippage may cause particle generation and/or contamination). Furthermore, the dynamic mounting device 824 comprises a thermal break 827 configured to reduce heat transfer between the dynamic mounting device 824 and the mounting structure 810.

Referring now to FIG. 9, a top view of a gas heating device 900 is presented according to another embodiment. The gas heating device 900 can be similar to the embodiment of FIG. 8A, and can further comprise a plurality of heating element zones 840 (A-C), each of which is electrically independent of one another. Each of the plurality of heating element zones 840 (A-C) comprises one or more heat sources 820, wherein each heat source 820 comprises resistive heating element 830 configured to receive an electrical current from one or more power sources.

The one or more resistive heating elements 830 may be electrically coupled in series, as shown in FIG. 9, using electrical interconnects 842, wherein electrical current is supplied to the serial connection of one or more resistive heating elements 830 via, for example, connection of a first terminal 841 (A-C) to the power source and a second terminal 844 (A-C) to electrical ground for the power source. Alternatively, the one or more resistive heating elements 830 may be electrically coupled in parallel.

The inventors have recognized that high quality, robust thin films may be produced on a substrate when, among other things, enabling the filament-assisted CVD or pyrolytic CVD system to spatially control various process mechanisms or parameters. Some of these process mechanisms may include: (1) modification and/or spatial/temporal control of the reaction zone at the heating element array, e.g., spatial and/or temporal adjustment of the film forming chemistry at the reaction zone; (2) modification and/or spatial/temporal control of the surface reactivity at the substrate or substrate holder, e.g., spatial and/or temporal adjustment of the substrate temperature; (3) modification and/or spatial/temporal control of the diffusion path length between the reaction zone (i.e., the heating element array) and the substrate or substrate holder; and (4) modification and/or spatial/temporal control of the diffusion path length between the injection zone (i.e., the injection of one or more additives) and the substrate or substrate holder.

Referring now to FIG. 10, a schematic cross-sectional view of a chemical vapor deposition system 1001 is depicted according to another embodiment. The chemical vapor deposition system 1001 comprises a substrate holder 1020 configured to support a substrate 1025, upon which the thin film is formed. The substrate holder is configured to control the temperature of the substrate at a temperature suitable for the film forming reactions. Additionally, the chemical vapor deposition system 1001 comprises a film forming composition delivery system 1030 configured to introduce a film forming composition to the substrate 1025 through a gas distribution system 1040. Furthermore, the chemical vapor deposition system 1001 comprises a gas heating device 1045 coupled to or mounted downstream from the gas distribution system 1040 and configured to chemically modify the film forming composition. Further yet, the chemical vapor deposition system 1001 comprises a remote source 1070 configured to introduce one or more additives before, during, and/or after the introducing of the film forming composition.

The gas heating device 1045 comprises a heating element array 1055 having a plurality of heating element zones 1055 (A,B,C) configured to receive a flow of a film forming composition from the film forming composition delivery system 1030 and the gas distribution system 1040 across or through the plurality of heating element zones 1055 (A,B,C) in order cause pyrolysis of one or more constituents of the film forming composition when heated. Each of the plurality of heating element zones 1055 (A,B,C) comprises one or more heating elements, and is configured electrically independent of one another, wherein each of the plurality of heating element zones is arranged to interact with at least a portion of the flow, and affect pyrolysis of and delivery of the film forming composition to different regions of the substrate 25.

One or more power sources 1050 are coupled to the gas heating device 1045, and configured to provide an electrical signal to each of the plurality of heating element zones 1055 (A,B,C) of heating element array 1055. For example, each of the plurality of heating element zones 1055 (A,B,C) of heating element array 1055 can comprise one or more resistive heating elements. When electrical current flows through and effects heating of the one or more resistive heating elements, the interaction of these heated elements with the film forming composition causes pyrolysis of one or more constituents of the film forming composition. As shown in FIG. 10, the one or more heating elements for each of the plurality of heating element zones 1055 (A,B,C) may be arranged in a plane, i.e., planar arrangement. Alternatively, the one or more heating elements for each of the plurality of heating element zones 1055 (A,B,C) may not be arranged in a plane, i.e., non-planar arrangement.

As shown in FIG. 10, the plurality of heating element zones 1055 (A,B,C) in the heating element array 1055 may be arranged within a plane 1034 substantially parallel with substrate 1025 and spaced away from substrate 1025 a distance 1035. Therein, a flow of film forming composition enters the chemical vapor deposition system 1001 through gas distribution system 1040, flows through heating element array 1055 into process space 1033, and flows downward through process space 1033 to substrate 1025 in a direction substantially normal to substrate 1025, i.e. a stagnation flow pattern. At least a portion of the flow of the film forming composition flows through each of the plurality of the heating element zones 1055 (A,B,C). The gas distribution system 1040 may be zoned in a manner such that an amount of film forming composition flowing to each of the plurality of heating element zones 1055 (A,B,C) is controllable.

The remote source 1070 comprises an injection array 1072 having one or more injection zones 1072 (A,B,C). The injection array 1072 may include injection zone(s) 1072 (A,B,C) located between the gas heating device 1045 and the substrate 1025 and beyond a peripheral edge of the gas heating device 1045, wherein the other injection zone 1072A is optional. Alternatively, the injection array 1072 comprises a plurality of injection zones 1072 (A,B,C). The remote source 1070 supplies the one or more injection zones 1072 (A,B,C) with one or more additives. The one or more additives may include a reactive composition containing atomic species, molecular species, excited species, metastable species, dissociated species, radical species, ionized species, etc.

As shown in FIG. 10, the plurality of injection zones 1072 (A,B,C) in the injection array 1072 may be arranged within a plane 1074 substantially parallel with substrate 1025 and spaced away from substrate 1025 a distance 1075. Therein, a flow of one or more additives enters the chemical vapor deposition system 1001 through injection array 1072, and flows downward through process space 1033 to substrate 1025. The injection array 1072 may be zoned in a manner such that an amount of the one or more additives flowing to various regions above substrate 1025 is controllable.

The plurality of heating element zones 1055 (A,B,C) and injection zones 1072 (A,B,C) correspond to different process regions 1033 (A-C) of the substrate 1025, respectively. For example, heating element zone 1055A and injection zone 1072A may correspond to process region 1033A located at a substantially central region of substrate 1025. Additionally, for example, heating element zones 1055B and 1055C, and injection zones 1072B and 1072C, may correspond to process regions 1033B and 1033C, respectively, located at a substantially edge or peripheral region of substrate 1025. Therefore, independent control of each of the plurality of heating element zones 1055 (A-C) and/or control of the amount of film forming composition directed to each of the plurality of heating element zones 1055 (A-C), and independent control of each of the plurality of injection zones 1072 (A,B,C), may be used to control processing parameters in each of the process regions 1033 (A-C).

Corresponding to the plurality of heating element zones 1055 (A-C) and injection zones 1072 (A-C), the substrate holder 1020 may comprise a plurality of temperature control zones for controlling a temperature of substrate 1025. The temperature control zones may align with process regions 1033 (A-C) and/or the plurality of heating element zones 1055 (A-C) and injection zones 1072 (A-C).

For example, the substrate holder 1020 may comprise one or more temperature control elements 1022 (A-C) coupled to a temperature control system 1022 and corresponding to the plurality of temperature control zones for substrate 1025. The temperature control system 1022 can include a substrate heating system, or a substrate cooling system, or both. For example, temperature control elements 1022 (A-C) may include substrate heating elements and/or substrate cooling elements embedded within the substrate holder 1020. The temperature control elements 1022 (A-C) may correspond to the plurality of temperature control zones for substrate 1025 and the process regions 1033 (A-C). The temperatures of each region of substrate holder 1020 may be controlled by heating or cooling each region in the substrate holder 1020.

Additionally, for example, the substrate holder 1020 may comprise a substrate clamping system 1023A (e.g., electrical or mechanical clamping system) to clamp the substrate 1025 to the upper surface of substrate holder 1020. For example, substrate holder 1020 may include an electrostatic chuck (ESC). An ESC control system 1023 may be utilized to operate and control substrate clamping system 1023A.

Furthermore, for example, the substrate holder 1020 may facilitate the delivery of heat transfer gas to the back-side of substrate 1025 via a backside gas supply system 1024 to improve the gas-gap thermal conductance between substrate 1025 and substrate holder 1020. Such a system can be utilized when temperature control of the substrate is required at elevated or reduced temperatures. As shown in FIG. 10, the backside gas supply system 1024 may comprise one or more heat transfer gas supply zones 1024 (A-C) to controllably adjust heat transfer at the plurality of temperature control zones for controlling the temperature of substrate 1025. The heat transfer gas supply zones 1024 (A-C) may correspond to the plurality of heating element zones 1055 (A-C), the plurality of injection zones 1072 (A-C), and the process regions 1033 (A-C). The temperatures of each region of substrate 1025 may be controlled by independently varying the backside (e.g., helium, He) pressure at each of the heat transfer gas supply zones 1024 (A-C).

Referring still to FIG. 10, a controller 1080 is coupled to the film forming composition delivery system 1030, the one or more power sources 1050, the remote source 1070, the temperature control system 1022, the ESC control system 1023, and/or the backside gas supply system 1024 to perform at least one of monitoring, adjusting, or controlling a processing parameter at different regions of substrate 1025. For example, one or more of the aforementioned elements may be used to control film deposition uniformity on substrate 1025.

Referring now to FIG. 11, a schematic cross-sectional view of a chemical vapor deposition system 2001 is depicted according to another embodiment. The chemical vapor deposition system 2001 comprises a gas heating device 2045 coupled to or mounted downstream from the gas distribution system 1040 and configured to chemically modify the film forming composition. The gas heating device 2045 comprises a heating element array 2055 having a plurality of heating element zones 2055 (A,B,C). The chemical vapor deposition system 2001 further comprises a remote source 2070 configured to introduce one or more additives before, during, and/or after the introducing of the film forming composition.

Each of the plurality of heating element zones 2055 (A,B,C) of heating element array 2055 can comprise one or more resistive heating elements. When electrical current flows through and effects heating of the one or more resistive heating elements, the interaction of these heated elements with the film forming composition causes pyrolysis of one or more constituents of the film forming composition. As shown in FIG. 11, the one or more heating elements for each of the plurality of heating element zones 2055 (A,B,C) may be arranged in a plane, i.e., planar arrangement. Alternatively, the one or more heating elements for each of the plurality of heating element zones 2055 (A,B,C) may not be arranged in a plane, i.e., non-planar arrangement.

As shown in FIG. 11, at least one of the plurality of heating element zones 2055 (A,B,C) in the heating element array 2055 may be arranged within a first plane 2034A, while at least another of the plurality of heating element zones 2055 (A,B,C) in the heating element array 2055 may be arranged within a second plane 2034B. The first and second planes 2034A, 2034B may be substantially parallel with substrate 1025 and spaced away from substrate 1025 a distance 2035A, 2035B, respectively. However, the first plane 2034A and/or the second plane 2034B need not be oriented parallel with substrate 1025. Therein, a flow of film forming composition enters the chemical vapor deposition system 2001 through gas distribution system 1040, flows through heating element array 2055 into process space 1033, and flows downward through process space 1033 to substrate 1025 in a direction substantially normal to substrate 1025, i.e. a stagnation flow pattern.

The remote source 2070 comprises an injection array 2072 having one or more injection zones 2072 (A,B,C). The injection array 2072 may include injection zone(s) 2072 (A,B,C) located between the gas heating device 2045 and the substrate 1025 and beyond a peripheral edge of the gas heating device 2045, wherein the other injection zone 2072A is optional. Alternatively, the injection array 2072 comprises a plurality of injection zones 2072 (A,B,C). The remote source 2070 supplies the one or more injection zones 2072 (A,B,C) with one or more additives. The one or more additives may include a reactive composition containing atomic species, molecular species, excited species, metastable species, dissociated species, radical species, ionized species, etc.

As shown in FIG. 11, at least one of the plurality of injection zones 2072 (A,B,C) in the injection array 2072 may be arranged within a first plane 2074A, while at least another of the plurality of injection zones 2072 (A,B,C) in the injection array 2072 may be arranged within a second plane 2074B. The first and second planes 2074A, 2074B may be spaced away from substrate 1025 a distance 2075A, 2075B, respectively. However, the first plane 2074A and/or the second plane 2074B need not be oriented parallel with substrate 1025. Therein, a flow of one or more additives enters the chemical vapor deposition system 2001 through injection array 2072, and flows downward through process space 1033 to substrate 1025.

The plurality of heating element zones 2055 (A,B,C) and injection zones 2072 (A,B,C) correspond to different process regions 1033 (A-C) of the substrate 1025, respectively. For example, heating element zone 2055A and injection zone 2072A may correspond to process region 1033A located at a substantially central region of substrate 1025. Additionally, for example, heating element zones 2055B and 2055C, and injection zones 2072B and 2072C, may correspond to process regions 1033B and 1033C, respectively, located at a substantially edge or peripheral region of substrate 1025. By varying the location of the first plane 2034A and the second plane 2034B, the distances 2035A and 2035B, respectively, between the reaction zone at each of the plurality of heating element zones 2055 (A-C) and substrate 1025 may be varied to provide additional control of the processing parameters at each of the process regions 1033 (A-C). Furthermore, by varying the location of the first plane 2074A and the second plane 2074B, the distances 2075A and 2075B, respectively, between the injection zone at each of the plurality of injection zones 2072 (A-C) and substrate 1025 may be varied to provide additional control of the processing parameters at each of the process regions 1033 (A-C).

Other details relating to the chemical vapor deposition system and the gas heating device may be found in pending U.S. patent application Ser. No. 11/693,067, entitled “Vapor deposition system and method of coating”, published as U.S. Patent Application Publication No. 2008/0241377A1, and filed on Mar. 29, 2007; pending U.S. patent application Ser. No. 12/044,574, entitled “Gas heating device for a vapor deposition system”, published as U.S. Patent Application Publication No. 2009/0223452A1, and filed on Mar. 7, 2008; pending U.S. patent application Ser. No. 12/559,398, entitled “High temperature gas heating device for a vapor deposition system”, and filed on Sep. 14, 2009; pending U.S. patent application Ser. No. 12/814,278, entitled “Apparatus for chemical vapor deposition control”, and filed on Jun. 11, 2010; and pending U.S. patent application Ser. No. 12/814,301, entitled “Method for chemical vapor deposition control”, and filed on Jun. 11, 2010; the contents of which are herein incorporated by reference in their entirety.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method of performing a filament-assisted chemical vapor deposition process, comprising:
providing a substrate holder in a process chamber of a chemical vapor deposition system;
providing a non-ionizing heat source, separate from said substrate holder, in said process chamber, said non-ionizing heat source including a gas heating device;
disposing a substrate on said substrate holder;
introducing a film forming composition to said process chamber;
thermally fragmenting said film forming composition by flowing said film forming composition through or over said gas heating device;
remotely producing a reactive composition;
introducing said reactive composition to said process chamber to interact with said substrate; and
forming a thin film on said substrate in said process chamber,
wherein said reactive composition is introduced sequentially and/or simultaneously with said introducing said film forming composition.

2. The method of claim 1, wherein said reactive composition is introduced to said process chamber to pre-treat a surface on said substrate preceding said forming said thin film.

3. The method of claim 1, wherein said reactive composition is introduced to said process chamber to post-treat a surface on said substrate following said forming said thin film.

4. The method of claim 1, wherein said reactive composition is introduced to said process chamber to assist film forming reactions at a surface on said substrate during said forming said thin film.

5. The method of claim 1, further comprising:
altering a surface functionality at a surface of said substrate by introducing said reactive composition.

6. The method of claim 1, further comprising:
hydrolizing a surface of said substrate by introducing said reactive composition.

7. The method of claim 1, wherein said reactive composition contains an ion specie, a radical specie, or a metastable specie, or any combination of two or more thereof.

8. The method of claim 1, wherein said reactive composition contains water vapor (H₂O), a hydroxyl radical, a hydroxide ion, atomic hydrogen, a hydrogen ion, atomic oxygen, an oxygen ion, ozone, atomic nitrogen, a nitrogen ion, or a peroxide, or any combination of two or more thereof.

9. The method of claim 1, wherein said producing said reactive composition comprises:
forming said reactive composition using a remote source, said remote source including a remote plasma generator, a remote radical generator, a remote ozone generator, or a remote water vapor generator, or any combination of two or more thereof; and
flowing said reactive composition from said remote source to said process chamber.

10. The method of claim 1, wherein said gas heating device comprises a heating element array, said heating element array including one or more resistive heating elements through which and/or over which said film forming composition flows.

11. The method of claim 1, wherein said substrate holder comprises one or more temperature control zones.

12. The method of claim 11, further comprising:
independently controlling a temperature of said substrate at said one or more temperature control zones.

13. The method of claim 12, further comprising:
disposing a gas heating device comprising a plurality of heating element zones in said process chamber, each of said plurality of heating element zones having one or more resistive heating elements; and
independently controlling a temperature of each of said plurality of heating element zones.

14. The method of claim 13, wherein said substrate holder comprises a plurality of temperature control zones, each of said plurality of temperature control zones uniquely corresponds to each of said plurality of heating element zones.

15. The method of claim 13, further comprising:
independently controlling a flow rate of said film forming composition to each of said plurality of heating element zones.

16. The method of claim 13, further comprising:
spacing each of said plurality of heating element zones from said substrate to control a diffusion path length between a reaction zone at each of said plurality of heating element zones and a surface of said substrate.

16. (canceled)

17. The method of claim 13, further comprising:
introducing said reactive composition at a plurality of injection zones in said process chamber; and
spacing each of said plurality of injection zones from said substrate to control a diffusion path length between each of said plurality of injection zones and a surface of said substrate.

18. The method of claim 1, wherein said film forming composition contains a chemical precursor to said thin film on said substrate and a radical initiator, and wherein a heat source temperature for said gas heating device is selected to achieve pyrolysis of said radical initiator, said heat source temperature ranges from about 200 degrees C. to about 700 degrees C.

19. The method of claim 1, wherein said film forming composition contains a chemical precursor to said thin film on said substrate, and wherein a heat source temperature for said gas heating device is selected to achieve pyrolysis of said chemical precursor, said heat source temperature ranges from about 600 degrees C. to about 1100 degrees C.

20. The method of claim 1, wherein said substrate is controllably maintained at a substrate temperature ranging up to about 80 degrees C.
